(19) United States
(12) Patent Application Publication
(10) Pub. No.: US 2022/0365858 A1
(43) Pub. Date: Nov. 17, 2022

(54) NETWORK INSPECTION SYSTEM AND NETWORK INSPECTION METHOD

(71) Applicant: Mitsubishi Electric Corporation, Tokyo (JP)

(72) Inventor: Yasuhiro OMORI, Tokyo (JP)

(73) Assignee: Mitsubishi Electric Corporation, Tokyo (JP)

(21) Appl. No.: 17/876,957

(22) Filed: Jul. 29, 2022

Related U.S. Application Data
(63) Continuation of application No. PCT/JP2020/011824, filed on Mar. 17, 2020.

(51) Int. Cl. G06F 11/30; G06F 11/273

(52) U.S. Cl. CPC G06F 11/3041; G06F 11/3062; G06F 11/273

(57) ABSTRACT

A network (101) is composed of a bus branched at one or more points, and one or more nodes are connected to each branch line. An inspection control unit (220) outputs a base signal. An amplification control unit (210) determines an amplification period and an amplification factor based on a parameter, and amplifies the base signal with the determined amplification factor during the determined amplification period. The inspection control unit (220) accepts, as an inspection signal, the base signal whose waveform has changed as a result of flowing though the bus, and judges whether or not there is a new node connected to the bus based on a waveform of the inspection signal.

### CROSS REFERENCE TO RELATED APPLICATIONS

This application is a Continuation of PCT International Application No. PCT/JP2020/011824 filed on Mar. 17, 2020, which is hereby expressly incorporated by reference into the present application.

### TECHNICAL FIELD

The present disclosure relates to a technique of detecting an invalid node connected to a network such as an in-vehicle network.

### BACKGROUND ART

There is a technique called TDR.

TDR is a technique of transmitting a pulse signal of any length to a transmission line, such as a power transmission line, so as to detect a node failure on the transmission line. A node failure is detected when a waveform of the pulse signal changes from a normal waveform.

TDR is an abbreviation for Time Domain Reflectometry.

Patent Literature 1 discloses a technique that applies TDR to an in-vehicle network so as to detect an invalid node connected to the in-vehicle network.

### CITATION LIST

### Patent Literature

Patent Literature 1: WO 2018/146747 A1

### SUMMARY OF INVENTION

### TECHNICAL PROBLEM

When a bus of a network is branched, the voltage of a pulse signal for detection decreases. Accordingly, a reflected wave that indicates presence of a node connected to the network becomes smaller. For this reason, it is difficult to detect the reflected wave. Therefore, it is difficult to detect an invalid node connected to the network.

An object of the present disclosure is to make it possible to detect an invalid node connected to a network even when a bus of the network is branched.

### SOLUTION TO PROBLEM

A network inspection system according to the present disclosure includes

a signal output unit to output a base signal, the base signal being a pulse signal for inspecting a network which is composed of a bus branched at one or more points and in which one or more nodes are connected to each branch line;

an amplification condition determination unit to determine an amplification period during which the base signal is to be amplified and an amplification factor in the amplification period, based on a parameter indicating information about branching of the bus;

a signal amplification unit to amplify the base signal with the determined amplification factor during the determined amplification period; and

an inspection unit to accept, as an inspection signal, the base signal whose waveform has changed as a result of flowing through the bus, and judge whether or not there is a new node connected to the bus based on a waveform of the inspection signal.

### ADVANTAGEOUS EFFECTS OF INVENTION

According to the present disclosure, an invalid node connected to a network can be detected even when a bus of the network is branched.

### BRIEF DESCRIPTION OF DRAWINGS

FIG. 1 is a configuration diagram of a network inspection system 100 in a first embodiment;

FIG. 2 is a configuration diagram of a network inspection apparatus 200 in the first embodiment;

FIG. 3 is a flowchart of a network inspection method in the first embodiment;

FIG. 4 is a diagram describing a judgment method in the first embodiment;

FIG. 5 is a diagram describing the judgment method in the first embodiment;

FIG. 6 is a diagram describing amplification control (S110) in the first embodiment;

FIG. 7 is a diagram describing the amplification control (S110) in the first embodiment;

FIG. 8 is a diagram describing the amplification control (S110) in the first embodiment;

FIG. 9 is a flowchart of the amplification control (S110) in the first embodiment;

FIG. 10 is a configuration diagram of the network inspection system 100 in a second embodiment;

FIG. 11 is a configuration diagram of the network inspection apparatus 200 in the second embodiment;

FIG. 12 is a diagram describing voltage monitoring in the second embodiment;

FIG. 13 is a flowchart of the voltage monitoring in the second embodiment;

FIG. 14 is a configuration diagram of the network inspection system 100 in a third embodiment;

FIG. 15 is a flowchart of parameter generation in the third embodiment;

FIG. 16 is a diagram describing a generation method in the third embodiment; and

FIG. 17 is a hardware configuration diagram of the network inspection apparatus 200 in the embodiments.

### DESCRIPTION OF EMBODIMENTS

In the embodiments and drawings, the same elements or corresponding elements are denoted by the same reference sign. Description of an element denoted by the same reference sign as that of an element that has been described will be omitted or simplified as appropriate. Arrows in diagrams mainly indicate flows of data or flows of processing.

### First Embodiment

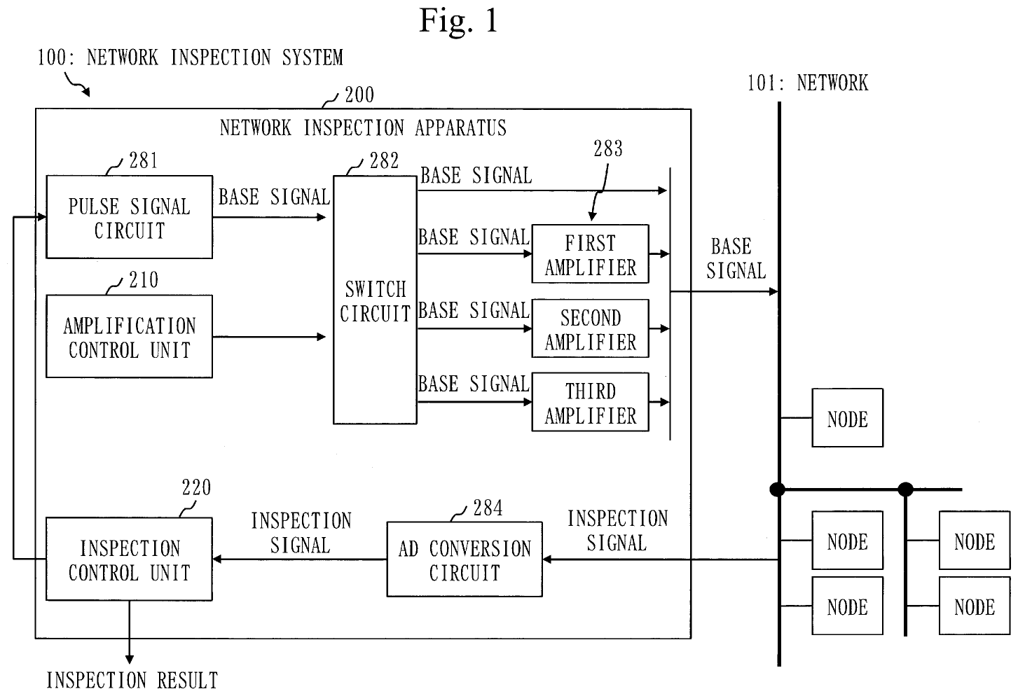

A network inspection system 100 will be described based on FIGS. 1 to 9.

***Description of Configurations***

Based on FIG. 1, a configuration of the network inspection system 100 will be described.

The network inspection system 100 is realized by a network inspection apparatus 200. The network inspection apparatus 200 may be composed of a plurality of apparatuses.

The network inspection apparatus 200 is connected to a network 101.

A specific example of the network 101 is an in-vehicle network. In the in-vehicle network, communication is performed using a protocol called a controller area network (CAN), for example.

In the first embodiment, the network 101 is composed of a bus branched at one or more points. One or more nodes are connected to each branch line. In the network 101 of FIG. 1, a filled circle represents a branch point.

Each node is equipment called an ECU, a controller, or a device, for example.

ECU is an abbreviation for Electronic Control Unit.

An ECU for power windows, an ECU for power steering, an ECU for brakes, an ECU for key unlocking, and so on are connected to the in-vehicle network.

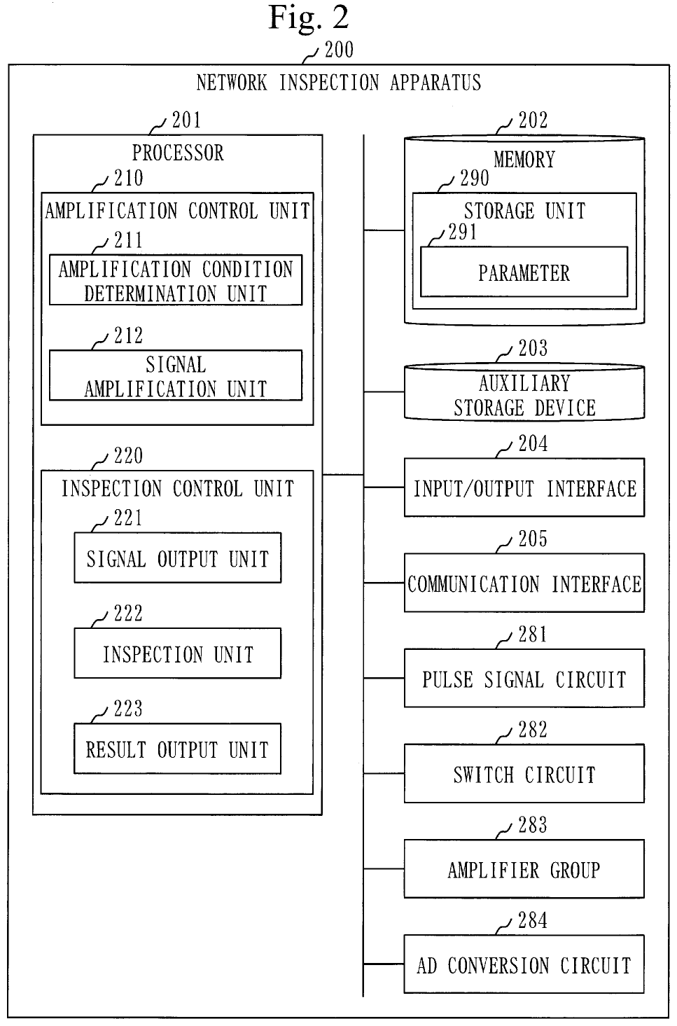

Based on FIG. 2, a configuration of the network inspection apparatus 200 will be described.

The network inspection apparatus 200 is a computer that includes hardware such as a processor 201, a memory 202, an auxiliary storage device 203, an input/output interface 204, and a communication interface 205. The network inspection apparatus 200 further includes hardware such as a pulse signal circuit 281, a switch circuit 282, an amplifier group 283, and an AD conversion circuit 284.

These hardware components are connected with one another through signal lines.

The processor 201 is an IC that performs operational processing and controls other hardware components. For example, the processor 201 is a CPU or a DSP.

IC is an abbreviation for Integrated Circuit.

CPU is an abbreviation for Central Processing Unit.

DSP is an abbreviation for Digital Signal Processor.

The memory 202 is a volatile or non-volatile storage device. The memory 202 is also called a main storage device or a main memory. For example, the memory 202 is a RAM. Data stored in the memory 202 is saved in the auxiliary storage device 203 as necessary.

RAM is an abbreviation for Random Access Memory.

The auxiliary storage device 203 is a non-volatile storage device. For example, the auxiliary storage device 203 is a ROM, an HDD, or a flash memory. Data stored in the auxiliary storage device 203 is loaded into the memory 202 as necessary.

ROM is an abbreviation for Read Only Memory.

HDD is an abbreviation for Hard Disk Drive.

The input/output interface 204 is a port to which an input device and an output device are connected. For example, the input/output interface 204 is a USB terminal, the input device is a keyboard and a mouse, and the output device is a display.

USB is an abbreviation for Universal Serial Bus.

The communication interface 205 is an interface for communication. For example, the communication interface 205 is a communication port. Signals are input to and output from the network 101 via the communication interface 205.

The pulse signal circuit 281 is a circuit that generates a pulse signal. A pulse signal is also called a step wave.

The switch circuit 282 is a circuit that switches an output destination of a pulse signal.

The amplifier group 283 is a plurality of amplifiers. The plurality of amplifiers amplify pulse signals with respectively different amplification factors.

The AD conversion circuit 284 is a circuit that converts an analog signal into a digital signal. The AD conversion circuit 284 is also called an AD converter or a converter.

The network inspection apparatus 200 includes elements such as an amplification control unit 210 and an inspection control unit 220. The amplification control unit 210 includes elements such as an amplification condition determination unit 211 and a signal amplification unit 212. The inspection control unit 220 includes elements such as a signal output unit 221, an inspection unit 222, and a result output unit 223. These elements are realized by software.

The auxiliary storage device 203 stores a network inspection program to cause a computer to function as the amplification control unit 210 and the inspection control unit 220. The network inspection program is loaded into the memory 202 and executed by the processor 201.

The auxiliary storage device 203 further stores an OS. At least part of the OS is loaded into the memory 202 and executed by the processor 201.

The processor 201 executes the network inspection program while executing the OS.

OS is an abbreviation for Operating System.

Input data and output data of the network inspection program are stored in a storage unit 290. For example, a parameter 291 to be input to the network inspection program is stored in the storage unit 290.

The memory 202 functions as the storage unit 290. However, a storage device such as the auxiliary storage device 203, a register in the processor 201, and a cash memory in the processor 201 may function as the storage unit 290 in place of the memory 202 or together with the memory 202.

The network inspection apparatus 200 may include a plurality of processors as an alternative to the processor 201. The plurality of processors share the functions of the processor 201.

The network inspection program can be recorded (stored) in a computer readable format in a non-volatile recording medium such as an optical disc or a flash memory.

***Description of Operation***

A procedure for operation of the network inspection system 100 is equivalent to a network inspection method. The procedure for the operation of the network inspection system 100 is also equivalent to a procedure for processing by the network inspection program.

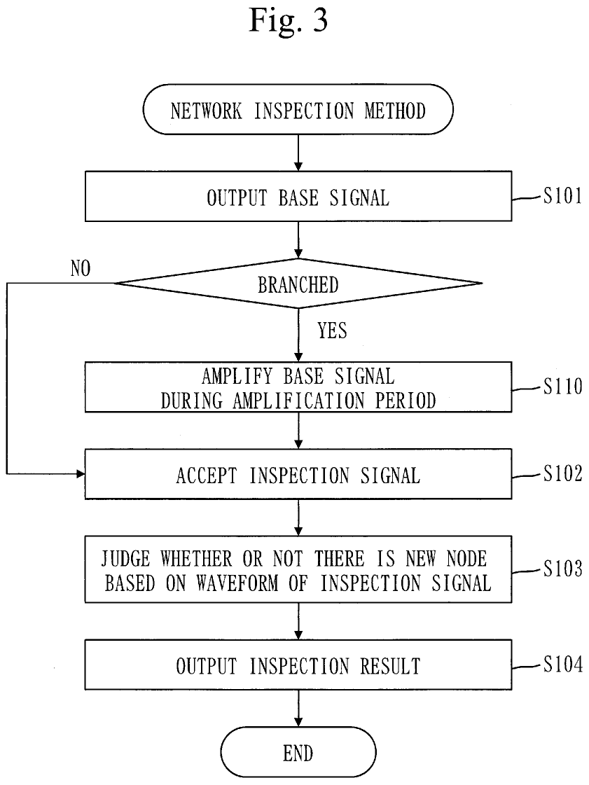

Based on FIG. 3, the network inspection method will be described.

In step S101, the signal output unit 221 outputs a base signal. The base signal is a pulse signal for inspecting the network 101.

Specifically, the signal output unit 221 inputs a signal output command to the pulse signal circuit 281. Then, the pulse signal circuit 281 generates a pulse signal. The generated pulse signal is the base signal.

The base signal is input to the switch circuit 282.

If the bus of the network 101 is branched, processing proceeds to step S110. In the first embodiment, processing proceeds to step S110.

If the network 101 is not branched, processing proceeds to step S102.

In step S110, the amplification control unit 210 amplifies the base signal during an amplification period determined by the parameter 291.

Details of step S110 will be described later.

In step S102, the inspection unit 222 accepts the base signal whose waveform has changed as a result of flowing through the bus of the network 101. The accepted base signal will be referred to as an “inspection signal”.

Specifically, the base signal flows through the bus of the network 101 and is input to the AD conversion circuit 284. The AD conversion circuit 284 converts the base signal, which is an analog signal, into a digital signal and outputs the base signal. The converted base signal is input to the inspection unit 222. Then, the inspection unit 222 accepts the input base signal.

In step S103, the inspection unit 222 judges whether or not there is a new node connected to the bus of the network 101 based on a waveform of the inspection signal. A technique called TDR is applied for the judgment.

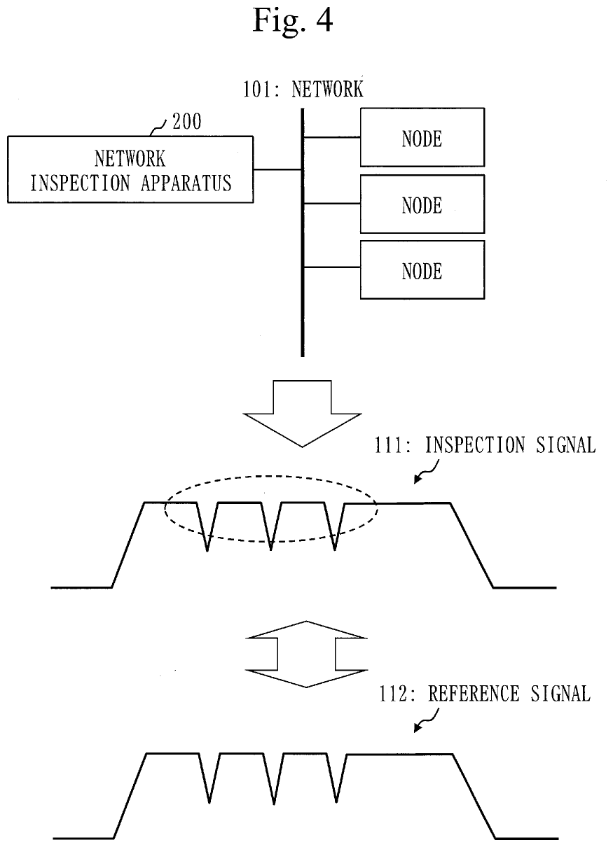

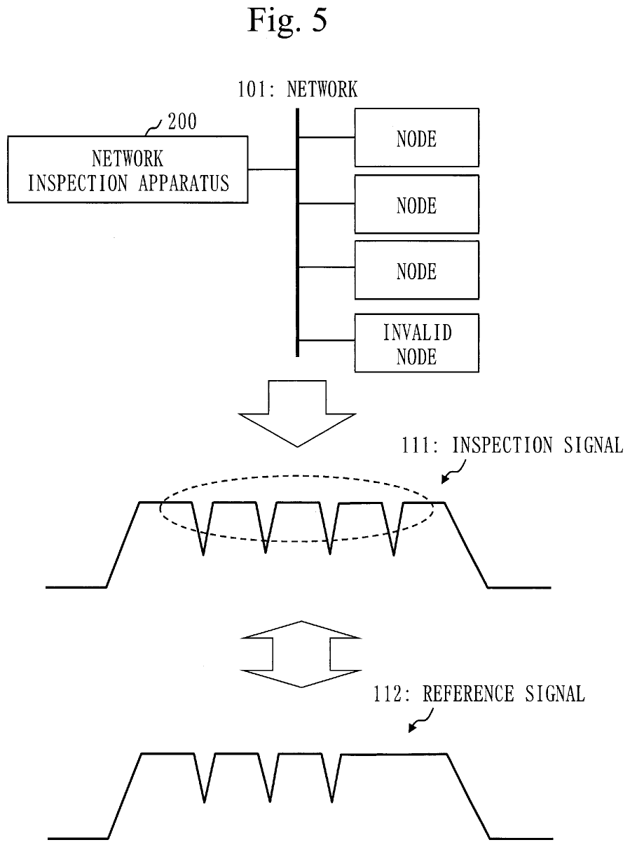

Based on FIGS. 4 and 5, a judgment method in step S103 will be described.

In FIG. 4, three nodes are connected to the network 101. These nodes are normal nodes.

A waveform of an inspection signal 111 contains reflected waves the number of which corresponds to the number of nodes connected to the bus of the network 101. Therefore, the waveform of the inspection signal 111 contains three reflected waves corresponding to the three nodes (see a dashed circle).

The inspection unit 222 compares the waveform of the inspection signal 111 with a waveform of a reference signal 112. The waveform of the reference signal 112 is equivalent to a waveform of an inspection signal that is obtained when only normal nodes are connected to the bus of the network 101. Data indicating the waveform of the reference signal 112 is prepared in advance.

The waveform of the inspection signal 111 matches the waveform of the reference signal 112. Therefore, the inspection unit 222 judges that no invalid node is connected to the bus of the network 101. That is, the inspection unit 222 judges that there is no new node connected to the bus of the network 101.

In FIG. 5, four nodes are connected to the bus of the network 101. One of the nodes is an invalid node.

The waveform of the inspection signal 111 contains four reflected waves corresponding to the four nodes (see a dashed circle). Therefore, the waveform of the inspection signal 111 does not match the waveform of the reference signal 112. Therefore, the inspection unit 222 judges that an invalid node is connected to the bus of the network 101. That is, the inspection unit 222 judges that there is a new node connected to the bus of the network 101.

Referring back to FIG. 3, step S104 will be described.

In step S104, the result output unit 223 outputs an inspection result. The inspection result indicates whether or not there is a new node connected to the bus of the network 101.

For example, the result output unit 223 displays the inspection result on the display.

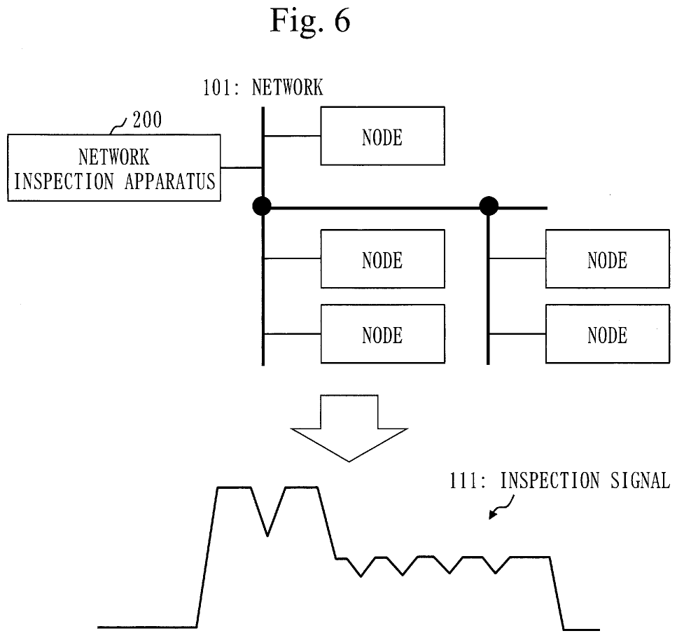

Based on FIGS. 6 to 8, an outline of amplification control (S110) will be described.

The description begins based on FIG. 6.

The bus of the network 101 is branched. For example, there are usually branches in the in-vehicle network.

When the bus of the network 101 is branched, the voltage of the inspection signal 111 decreases during a specific period depending on a state of branching. Accordingly, reflected waves become smaller. Therefore, it is difficult to detect the reflected waves.

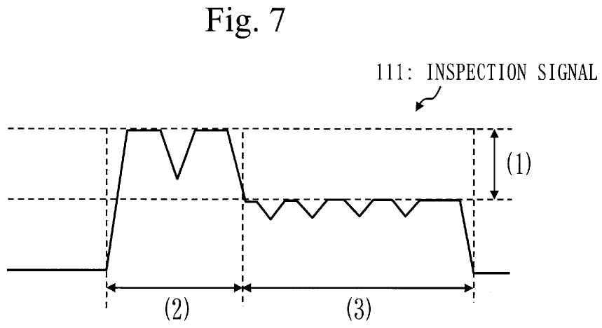

The description continues based on FIG. 7.

The following are determined depending on the state of branching of the bus: (1) a magnitude of a decrease in the voltage, (2) a length of a period until the voltage decreases, and (3) a length of a period during which the voltage decreases.

(1) The magnitude of a decrease in the voltage is determined by the number of branches.

(2) The length of the period until the voltage decreases is determined by a length from the network inspection apparatus 200 to a branch point.

(3) The length of the period during which the voltage decreases is determined by a length from the branch point to an end of the bus.

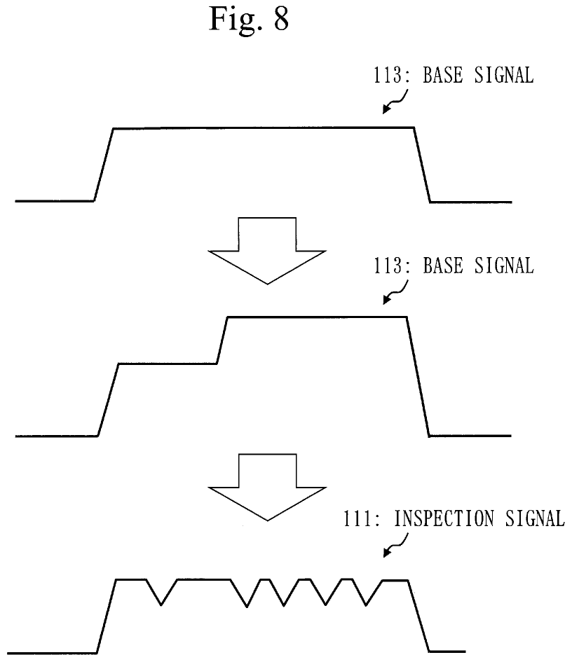

The description continues based on FIG. 8.

In the amplification control (S110), therefore, a base signal 113 is amplified depending on the state of branching of the bus.

As a result, the inspection signal 111 similar to an inspection signal when the bus is not branched is obtained. Since reflected waves are not small, it is not difficult to detect the reflected waves.

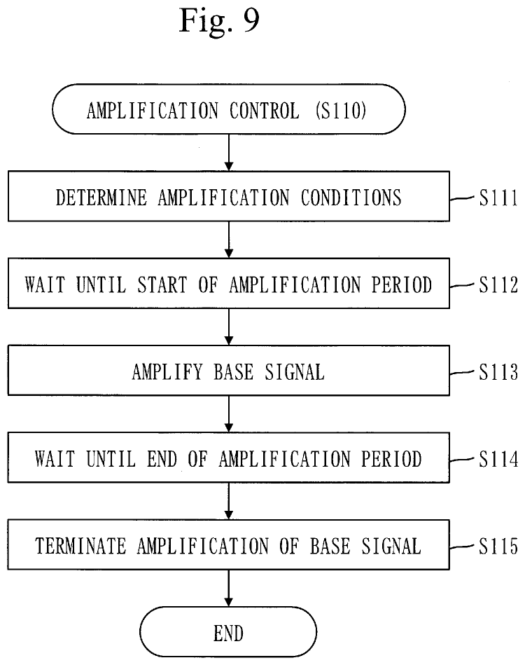

Based on FIG. 9, a procedure for the amplification control (S110) will be described.

Step S111 may be performed before the base signal is output (step S101 in FIG. 3).

In step S111, the amplification condition determination unit 211 determines amplification conditions based on the parameter 291. Specific amplification conditions are an amplification period and an amplification factor.

The parameter 291 indicates branch information. The branch information is information about branching of the bus of the network 101.

The amplification period is the period during which the base signal is amplified. For example, the amplification period is identified by an amplification timing and a period length. The amplification timing is the timing at which the amplification period starts. The period length is the length of the amplification period.

The amplification factor is the magnitude of amplification.

The branch information includes the number of branches. For example, the number of branches is the number of branch points or the number of ends of the bus.

The amplification condition determination unit 211 determines a higher amplification factor as the number of branches is larger. That is, the larger the number of branches, the higher the amplification factor. When the number of branches is n, the amplification factor is n times, for example.

Specifically, the amplification condition determination unit 211 selects one amplifier corresponding to the number of branches. The amplification factor of the selected amplifier becomes the determined amplification factor. For example, a first amplifier is selected when the number of branches is 1 to 5, a second amplifier is selected when the number of branches is 6 to 10, and a third amplifier is selected when the number of branches is 11 or more.

The branch information includes a branch point distance. The branch point distance is the distance from a base point to a branch point. For example, the branch point distance is the distance from an output port for the base signal (of the network inspection apparatus 200) to the nearest branch point (first branch point). An input point of the base signal is a location where the base signal is input in the bus.

The amplification condition determination unit 211 determines a later amplification period as the branch point distance is longer. That is, the longer the branch point distance, the later the amplification timing. When the branch point distance is one meter, the amplification timing is ten nanoseconds after the output of the base signal, for example.

The branch information includes an end distance. The end distance is the distance from a branch point to an end of the bus. For example, the end distance is the distance from the first branch point to the farthest end.

The amplification condition determination unit 211 determines a longer amplification period as the end distance is longer. That is, the longer the end distance, the longer the amplification period. When the end distance is two meters, the length of the amplification period is 20 nanoseconds, for example.

In step S112, the signal amplification unit 212 waits until the start of the determined amplification period (amplification timing).

During this time, the base signal output from the pulse signal circuit 281 is input to the switch circuit 282 and is transferred from the switch circuit 282 to the bus of the network 101 without passing through an amplifier. That is, the base signal that has not been amplified flows through the bus of the network 101.

In step S113, the signal amplification unit 212 amplifies the base signal with the determined amplification factor.

Specifically, the signal amplification unit 212 inputs a switch command in which the amplifier selected by the amplification condition determination unit 211 is specified to the switch circuit 282. The switch circuit 282 switches the output destination of the base signal to the amplifier specified by the switch command. The base signal is input to the amplifier and is amplified by the amplifier.

In step S114, the signal amplification unit 212 waits until the end of the determined amplification period. That is, the signal amplification unit 212 waits from the start of the amplification period until the period length of the amplification period elapses.

During this time, the base signal output from the pulse signal circuit 281 is input to the switch circuit 282 and is transferred from the switch circuit 282 to the bus of the network 101 via the amplifier. That is, the base signal that has been amplified flows through the bus of the network 101.

In step S115, the signal amplification unit 212 terminates the amplification of the base signal.

Specifically, the signal amplification unit 212 inputs a switch command in which no amplifier is specified to the switch circuit 282. The switch circuit 282 switches the output destination of the base signal to a signal line to which no amplifier is connected.

***Effects of the First Embodiment***

Even when the bus of the network 101 is branched, an invalid node connected to the network 101 can be detected.

The network inspection system 100 can supplement a decrease in the voltage of the inspection signal due to branching of the bus. As a result, inspection accuracy is maintained.

The network inspection system 100 determines the amplification period and the amplification factor depending on the state of branching, so that it can be applied to various networks with different states of branching.

### Second Embodiment

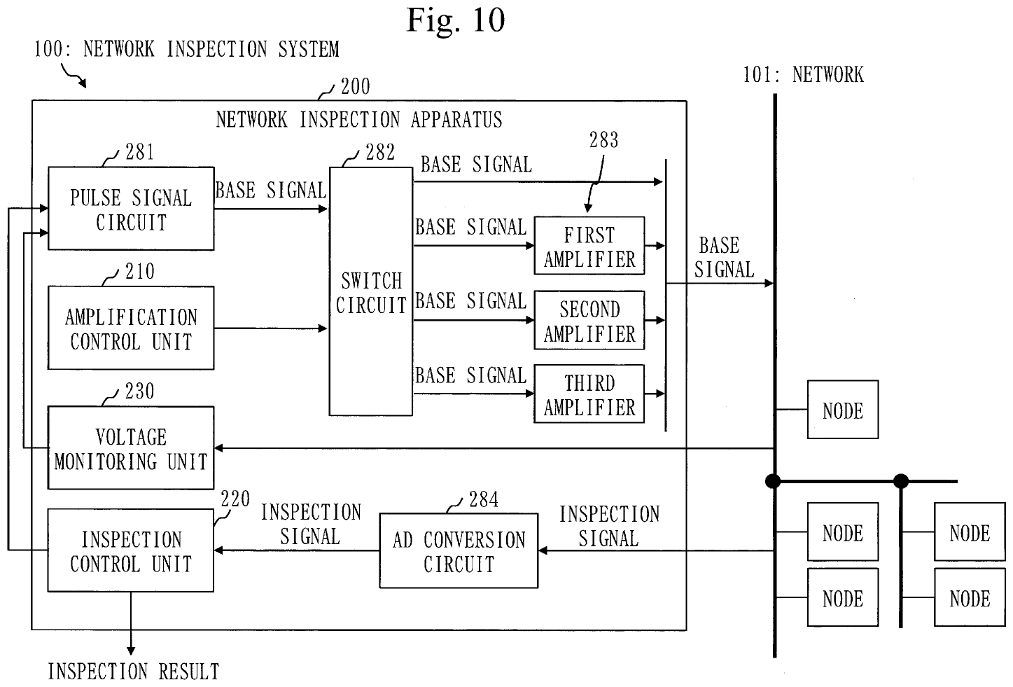

With regard to an embodiment in which the voltage of a base signal flowing through the bus of the network 101 is monitored, differences from the first embodiment will be mainly described based on FIGS. 10 to 13.

***Description of Configuration***

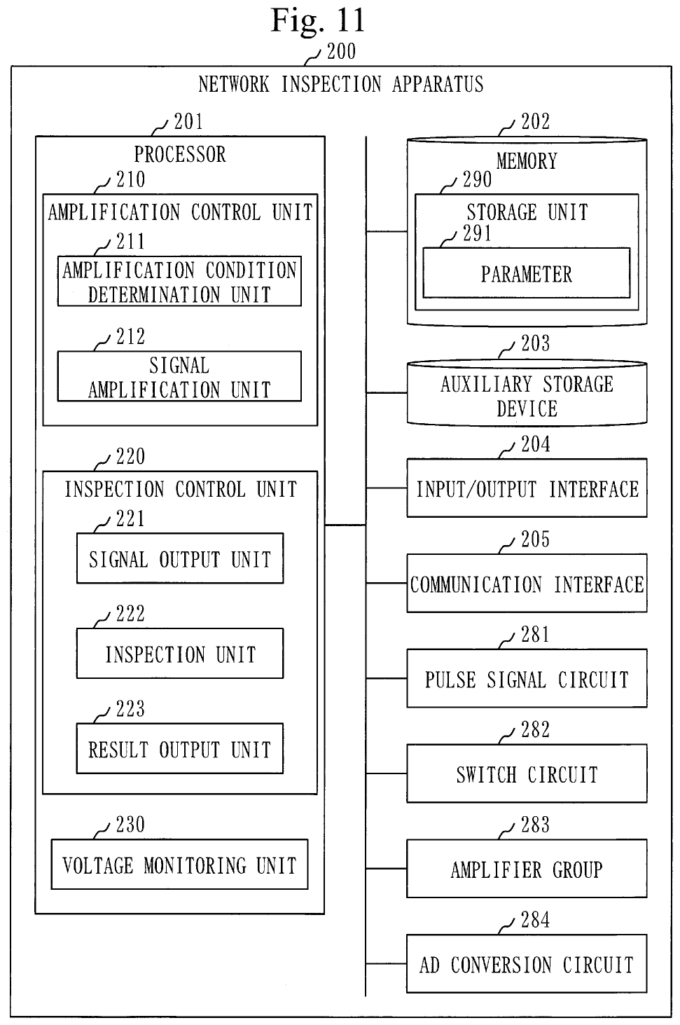

Based on FIGS. 10 and 11, a configuration of the network inspection apparatus 200 will be described.

The network inspection apparatus 200 further includes a voltage monitoring unit 230.

The network inspection program further causes a computer to function as the voltage monitoring unit 230.

***Description of Operation***

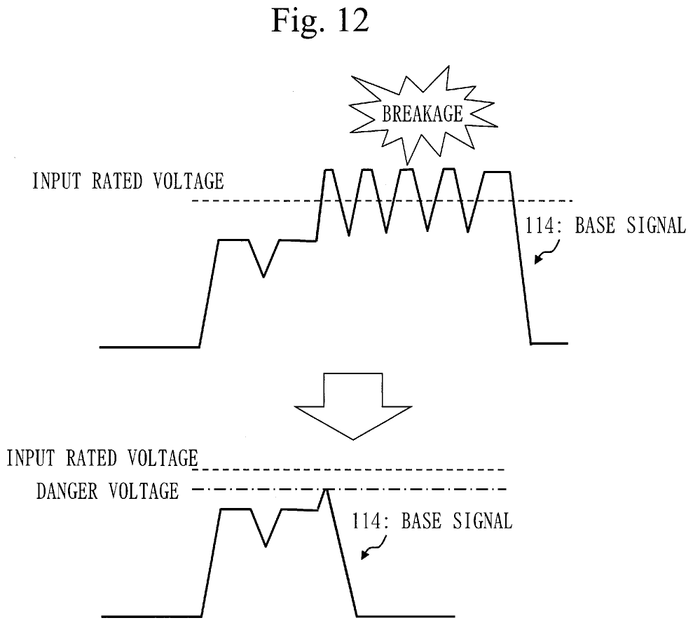

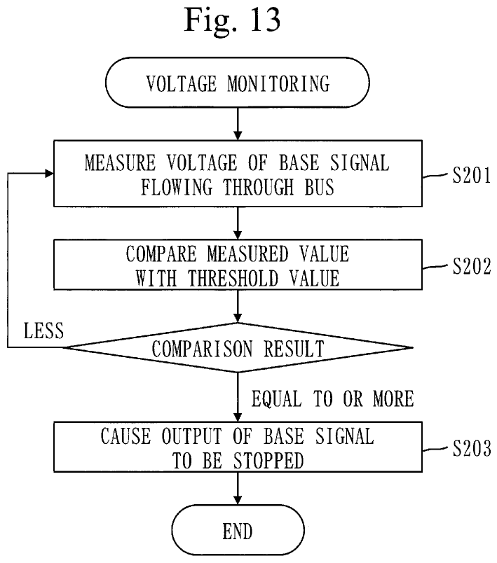

Based on FIGS. 12 and 13, voltage monitoring in the network inspection method will be described.

The voltage monitoring is processing performed by the voltage monitoring unit 230.

Based on FIG. 12, an outline of the voltage monitoring will be described.

A device to which a base signal 114 is input will be referred to as an “acceptance device”.

The base signal 114 is the base signal that flows through the bus of the network 101. The inspection signal is the base signal 114. The AD conversion circuit 284 is the acceptance device.

If the branched bus breaks, the voltage of the base signal 114 will not decrease. For this reason, if the base signal input to the bus is amplified, the voltage of the base signal 114 may exceed an input rated voltage. If the base signal 114 exceeding the input rated voltage is input to the acceptance device, the acceptance device will be broken.

Therefore, the voltage of the base signal 114 is monitored. If the voltage of the base signal 114 raises to a danger voltage, the output of the base signal is stopped.

The danger voltage is greater than the voltage of the base signal before being amplified and smaller than the input rated voltage of the acceptance device.

Based on FIG. 13, a procedure for the voltage monitoring will be described. The voltage monitoring is continued while the base signal is being output from the pulse signal circuit 281.

In step S201, the voltage monitoring unit 230 measures the voltage of the base signal flowing through the bus of the network 101. A value obtained by measurement, that is, a voltage value of the base signal will be referred to as a “measured value”.

In step S202, the voltage monitoring unit 230 compares the measured value with a threshold value. The threshold value is the value indicating the magnitude of the danger voltage and is determined in advance.

If the measured value is equal to or greater than the threshold value, processing proceeds to step S203.

If the measured value is less than the threshold value, processing proceeds to step S201.

In step S203, the voltage monitoring unit 230 causes the output of the base signal to be stopped.

Specifically, the voltage monitoring unit 230 inputs an output stop command to the pulse signal circuit 281. Then, the pulse signal circuit 281 stops the output of the base signal.

***Effects of the Second Embodiment***

The network inspection system 100 monitors the voltage of the base signal flowing through the bus of the network 101 to predict rising of the voltage of the base signal to a voltage that will break a device, and stops the output of the base signal. This can prevent a device from being broken.

### Third Embodiment

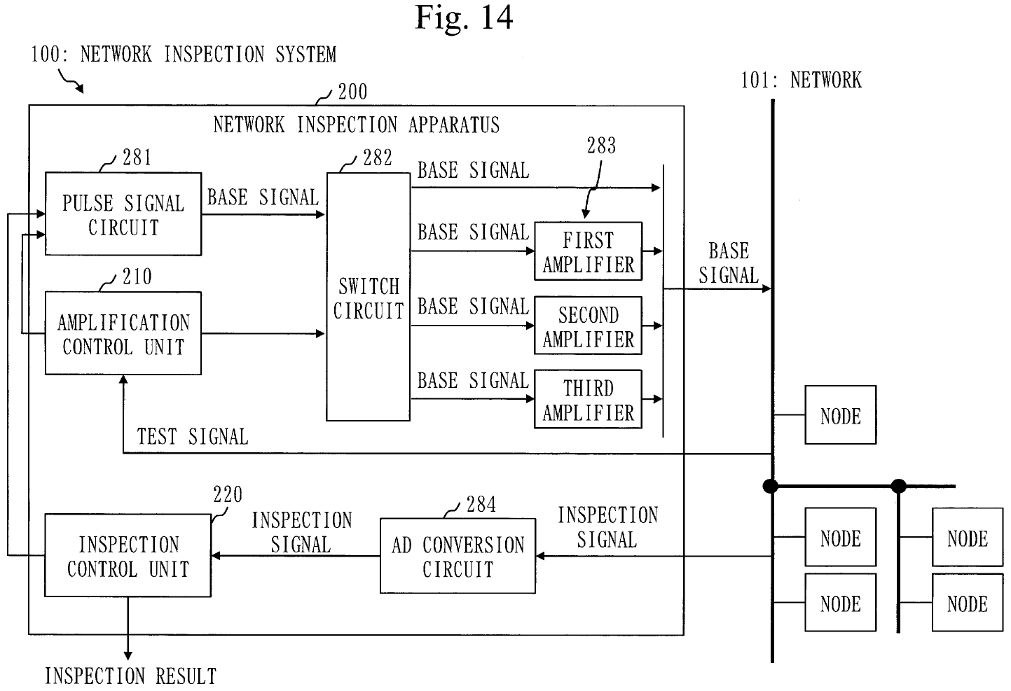

With regard to an embodiment in which amplification conditions are determined without using the parameter 291, differences from the first embodiment will be mainly described based on FIGS. 14 to 16.

***Description of Configuration***

Based on FIG. 14, a configuration of the network inspection system 100 will be described.

The constituent elements of the network inspection system 100 are the same as the constituent elements in the first embodiment (see FIG. 1).

However, the operation of the amplification condition determination unit 211 of the amplification control unit 210 is different from the operation in the first embodiment.

The network inspection system 100 may include the voltage monitoring unit 230 (see the second embodiment).

***Description of Operation***

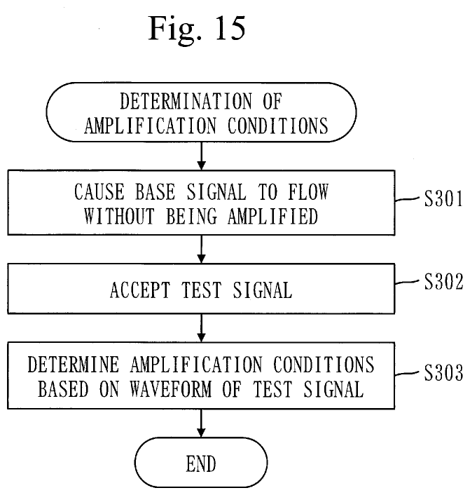

Based on FIG. 15, determination of amplification conditions in the network inspection method will be described.

The determination of amplification conditions is processing to replace step S111 (see FIG. 9). However, the determination of amplification conditions is performed before the base signal is output (step S101 in FIG. 3).

In step S301, the amplification condition determination unit 211 causes the base signal to flow through the bus of the network 101 without being amplified.

Specifically, the amplification condition determination unit 211 inputs a signal output command to the pulse signal circuit 281. Then, the pulse signal circuit 281 generates a pulse signal. The generated pulse signal is the base signal. The base signal is input to the switch circuit 282, and is input from the switch circuit 282 to the bus of the network 101 without passing through an amplifier.

In step S302, the amplification condition determination unit 211 accepts the base signal whose waveform has transformed as a result of flowing through the bus. The accepted base signal will be referred to as a “test signal”.

In step S303, the amplification condition determination unit 211 determines amplification conditions based on a waveform of the test signal. That is, the amplification condition determination unit 211 calculates an amplification period and an amplification factor.

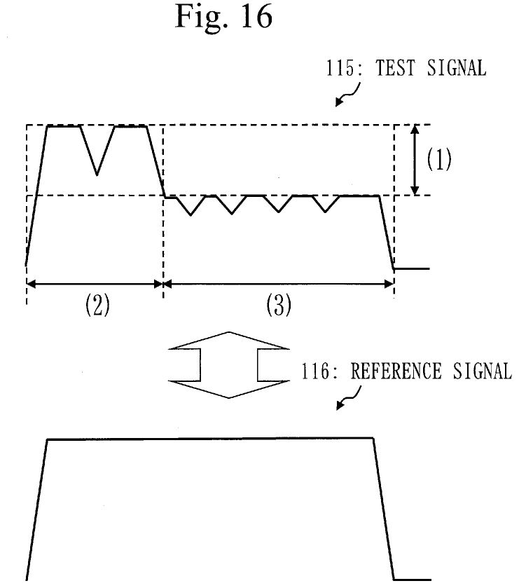

Based on FIG. 16, a determination method in step S303 will be described.

A waveform of a reference signal 116 is equivalent to a waveform of the inspection signal that is obtained when the bus of the network 101 is not branched, no node is connected to the bus of the network 101, and the base signal is not amplified. However, the condition that no node is connected to the bus of the network 101 may be omitted. Data indicating the waveform of the reference signal 116 is prepared in advance.

The amplification condition determination unit 211 compares a waveform of a test signal 115 with the waveform of the reference signal 116. Then, based on a comparison result, the amplification condition determination unit 211 calculates (1) a magnitude of a decrease in the voltage, (2) a period until the voltage decreases, and (3) a period during which the voltage decreases.

***Effects of the Third Embodiment***

The network inspection system 100 can determine amplification conditions without the parameter 291. This can save time and effort for manually creating the parameter 291.

Even networks 101 of the same type of vehicle do not have completely matching bus lengths and so on. However, the network inspection system 100 can determine optimum amplification conditions for each vehicle. This improves accuracy of detecting an invalid connection.

***Supplement to Embodiments***

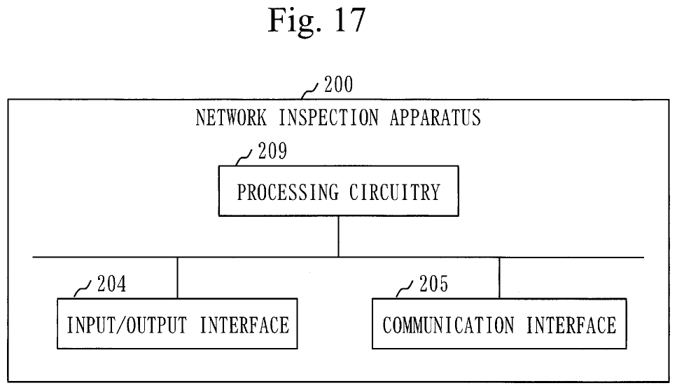

Based on FIG. 17, a hardware configuration of the network inspection apparatus 200 will be described.

The network inspection apparatus 200 includes processing circuitry 209.

The processing circuitry 209 is hardware that realizes the amplification control unit 210, the inspection control unit 220, and the voltage monitoring unit 230.

The processing circuitry 209 may be dedicated hardware, or may be the processor 201 that executes programs stored in the memory 202.

When the processing circuitry 209 is dedicated hardware, the processing circuitry 209 is, for example, a single circuit, a composite circuit, a programmed processor, a parallel-programmed processor, an ASIC, an FPGA, or a combination of these.

ASIC is an abbreviation for Application Specific Integrated Circuit.

FPGA is an abbreviation for Field Programmable Gate Array.

The network inspection apparatus 200 may include a plurality of processing circuits as an alternative to the processing circuitry 209. The plurality of processing circuits share the functions of the processing circuitry 209.

In the processing circuitry 209, some functions may be realized by dedicated hardware, and the rest of the functions may be realized by software or firmware.

As described above, the functions of the network inspection apparatus 200 can be realized by hardware, software, firmware, or a combination of these.

Each of the embodiments is an example of a preferred embodiment and is not intended to limit the technical scope of the present disclosure. Each of the embodiments may be implemented partially or may be implemented in combination with another embodiment. The procedures described using the flowcharts or the like may be changed as appropriate.

Each “unit” that is an element of the network inspection apparatus 200 may be interpreted as “process” or “step”.

### REFERENCE SIGNS LIST

100: network inspection system, 101: network, 111: inspection signal, 112: reference signal, 113: base signal, 114: base signal, 115: test signal, 116: reference signal, 200: network inspection apparatus, 201: processor, 202: memory, 203: auxiliary storage device, 204: input/output interface, 205: communication interface, 209: processing circuitry, 210: amplification control unit, 211: amplification condition determination unit, 212: signal amplification unit, 220: inspection control unit, 221: signal output unit, 222: inspection unit, 223: result output unit, 230: voltage monitoring unit, 281: pulse signal circuit, 282: switch circuit, 283: amplifier group, 284: AD conversion circuit, 290: storage unit, 291: parameter.

1. A network inspection system comprising:
processing circuitry to:
output a base signal, the base signal being a pulse signal for inspecting a network which is composed of a bus branched at one or more points and in which one or more nodes are connected to each branch line,
determine an amplification period during which the base signal is to be amplified and an amplification factor in the amplification period based on a parameter indicating information about branching of the bus,
amplify the base signal with the determined amplification factor during the determined amplification period, and
accept, as an inspection signal, the base signal whose waveform has changed as a result of flowing through the bus, and judge whether or not there is a new node connected to the bus based on a waveform of the inspection signal.

2. The network inspection system according to claim 1,
wherein the parameter indicates the number of branches, and
wherein the processing circuitry determines a higher amplification factor as the number of branches is larger.

3. The network inspection system according to claim 1,
wherein the parameter indicates a branch point distance, which is a distance from a base point to a branch point, and
wherein the processing circuitry determines a later amplification period as the branch point distance is longer.

4. The network inspection system according to claim 1,
wherein the parameter indicates an end distance, which is a distance from a branch point to an end of the bus, and
wherein the processing circuitry determines a longer amplification period as the end distance is longer.

5. The network inspection system according to claim 1,
wherein the processing circuitry monitors a voltage of the base signal flowing through the bus.

6. The network inspection system according to claim 5,
wherein the processing circuitry measures a voltage value of the base signal flowing through the bus, and causes output of the base signal to be stopped when the voltage value of the base signal flowing through the bus rises to a threshold value.

7. A network inspection system comprising:
processing circuitry to:
output a base signal, the base signal being a pulse signal for inspecting a network which is composed of a bus branched at one or more points and in which one or more nodes are connected to each branch line,
cause the base signal to flow through the bus without being amplified, accept the base signal whose waveform has changed as a result of flowing through the bus, as a test signal, and determine an amplification period during which the base signal is to be amplified and an amplification factor in the amplification period based on a waveform of the test signal,
amplify the base signal with the determined amplification factor during the determined amplification period, and
accept, as an inspection signal, the base signal whose waveform has changed as a result of flowing through the bus, and judge whether or not there is a new node connected to the bus based on a waveform of the inspection signal.

8. The network inspection system according to claim 7,
wherein the processing circuitry monitors a voltage of the base signal flowing through the bus.

9. The network inspection system according to claim 8,
wherein the processing circuitry measures a voltage value of the base signal flowing through the bus, and causes output of the base signal to be stopped when the voltage value of the base signal flowing through the bus rises to a threshold value.

10. A network inspection method comprising:
outputting a base signal, the base signal being a pulse signal for inspecting a network which is composed of a bus branched at one or more points and in which one or more nodes are connected to each branch line;
determining an amplification period during which the base signal is to be amplified and an amplification factor in the amplification period based on a parameter indicating information about branching of the bus;
amplifying the base signal with the determined amplification factor during the determined amplification period; and
accepting, as an inspection signal, the base signal whose waveform has changed as a result of flowing through the bus, and judging whether or not there is a new node connected to the bus based on a waveform of the inspection signal.

11. A network inspection method comprising:
outputting a base signal, the base signal being a pulse signal for inspecting a network which is composed of a bus branched at one or more points and in which one or more nodes are connected to each branch line;
causing the base signal to flow through the bus without being amplified, accepting the base signal whose waveform has changed as a result of flowing through the bus, as a test signal, and determining an amplification period during which the base signal is to be amplified and an amplification factor in the amplification period based on a waveform of the test signal;
amplifying the base signal with the determined amplification factor during the determined amplification period; and
accepting, as an inspection signal, the base signal whose waveform has changed as a result of flowing through the bus, and judging whether or not there is a new node connected to the bus based on a waveform of the inspection signal.
